(19) United States
(12) Patent Application Publication
(10) Pub. No.: US 2026/0324136 A1
(43) Pub. Date: Oct. 15, 2026

(54) OPTOELECTRONIC DEVICE AND METHOD FOR PROCESSING THE SAME

(71) Applicant: ams-OSRAM International GmbH, Regensburg (DE)

(72) Inventors: Tansen Varghese, Regensburg (DE); Martin Hetzl, Painten (DE)

(21) Appl. No.: 19/106,472

(22) PCT Filed: Sep. 4, 2023
(86) PCT No.: PCT/EP2023/074196

§ 371 Date: Feb. 25, 2025

(30) Foreign Application Priority Data
Sep. 5, 2022 (DE) 10 2022 122 480.5

(51) Int. Cl. H10H 20/816; H10H 20/01; H10H 20/812; H10H 20/824

(52) U.S. Cl. CPC H10H 20/8162; H10H 20/0133; H10H 20/812; H10H 20/824

(57) ABSTRACT

In an embodiment an optoelectronic device includes a mesa structured semiconductor layer stack having at least one of an n-doped layer or a p-doped layer and a structured active region arranged on a respective one of the n-doped layer or the p-doped layer; the structured active region configured to emit light, a regrown conductive barrier layer covering structured boundaries of the active region, the regrown conductive barrier layer comprising a material adjacent to the active region having a larger bandgap than the active region, respective contact layers electrically coupled to at least the one of the n-doped layer or the p-doped layer, respectively, wherein one of the contact layers is in electric contact with the regrown conductive barrier layer covering the structured boundaries of the active region, wherein a portion of the regrown conductive barrier layer extends substantially parallel to the one of the n-doped layer or the p-doped layer thereby surrounding the active layer.

### CROSS-REFERENCE TO RELATED APPLICATIONS

This patent application is a national phase filing under section 371 of PCT/EP2023/074196, filed Sep. 4, 2023, which claims the priority of German patent application no. 10 2022 122 480.5, filed Sep. 5, 2022, each of which is incorporated herein by reference in its entirety.

### TECHNICAL FIELD

The present invention concerns an optoelectronic device and a method for processing the same.

### BACKGROUND

Mesa etching of μ-LEDs is done to optically and electrically isolate the individual devices, or to isolate individual devices forming pixels in an array. Mesa etching will cause damages at the etch boundaries resulting in crystal defects, dangling bonds and other irregularities in the crystal structure. These irregularities cause non-radiative recombination (NRR) of carriers at the mesa edges.

At large pixels, in which the ratio of the overall area to the circumference is large, the above-mentioned defects do not substantially degrade the performance of the device. However, for small devices, the influence of such defects increases. Current spreading in the layers above and below the active region and through the active region contributes to carriers at the pixel edges, which then may recombine non-radiatively, lowering the quantum efficiency of the device.

The effect is particularly pronounced for InGaAIP-based μLEDs, which are usually applied for red color emission. This is due to the long diffusion length of charge carrier in the range of the size of the μ-LEDs devices and the high surface recombination velocities.

### SUMMARY

Embodiments overcome these and other issues particularly for μLEDs.

Different methods for passivating the mesa edges have been employed, depending on the material system, such that the number of defects is reduced and thus the performance improved. For the InGaAlP material system, which is usually used for yellow/red emission, there are two main approaches in order to reduce NRR at the mesa facet. Those are referred to as quantum well intermixing (QWI) and regrowth.

QWI is a method intentionally diffusing impurities or vacancies (impurity-free QWI) into the active region. The impurities and vacancies cause an intermixing of the quantum wells in the active region with adjacent high-bandgap barriers, leading to an overall increase of the local bandgap. When applied at the edges of the active region and the device, this results in a lateral potential barrier for charge carriers to avoid leakage from the inner core of the active region to its circumferential edges.

However, quantum well intermixing has technological limitations, in particular when processing small device sizes.

As an alternative, a so-called multi-step epitaxy (regrowth approach) can be conducted. Generally, a first epi including the active region is grown and the top surface then covered by a structured hard mask. The hard mask is used to etch the wafer surface removing portions of the active region leaving a QW island at the centre of the device defined later behind. The structure is then regrown on the same wafer with high-bandgap material in order to encapsulate the QW islands. A further etch may be conducted outside the QW islands to form pixels, which are larger than the islands.

In this way, a potential barrier in between the pixel core and the mesa facet appears, blocking charge carriers from diffusing to the surface. For GaN/InGaN-based μLEDs passivating dielectrics such as Al2O3 and SiO2 provided by atomic layer deposition (ALD) are used for reducing NRR at the pixel side facets. Pre-passivating etches and cleaning methods to remove, e.g., native oxides and defects, have also been employed in order to reduce NRR.

As an alternative, high-bandgap material used for encapsulating the QW islands are made of doped semiconductor material, and particularly can be made of the same material sued for the n-or p-doped layer. Consequently, the high-bandgap material becomes conductive and is in electrical contact with one of the doped layers. The conductive high-bandgap material extends along the expose side surface and may form an artificial pn-junction with the respective other layer surrounding the QW island. The pn-junction is biased in forward direction and will result in a leakage current during operation of the device. The inventor now proposes an additional blocking layer made of semiconductor material between the high barrier material and the layer configured to transport carrier into the active region such that the leakage current is blocked.

In some aspects, an optoelectronic device proposed by the inventor comprises a mesa structured semiconductor layer stack having at least one of an n-doped layer and a p-doped layer and a structured active region arranged on the respective one of the n-doped layer and the p-doped layer; the structured active region configured to emit light. The processing of the structured layer stack may follow conventional techniques, i.e. wafer wide epitaxially processing.

The device further comprises a regrown conductive barrier layer covering the structured boundaries of the active region. The regrown conductive barrier layer comprises a material having a larger bandgap than the active region adjacent to the active region. Respective contact layers are provided. These are electrically coupled to at least the one of the n-doped layer and the p-doped layer, respectively, wherein one of the contact layers is in electric contact with the regrown conductive barrier layer covering the structured boundaries of the active region.

As mentioned above, a portion of the regrown conductive barrier layer extends substantially parallel to the one of the n-doped and p-doped layer thereby surrounding the active layer. The optoelectronic device therefore comprises a structured first current blocking layer arranged between said portion of the regrown conductive barrier layer and the one of the n-doped and p-doped layer, said first current blocking layer comprising an opening. The one of the n-doped and p-doped layer is in conductive contact with the active region through the opening in the current blocking layer.

The regrown conductive barrier layer corresponds to the high bandgap material and is in contact with one of the contact layers feeding charge carriers towards the active region. The device forms a vertical μLED structure with both conductive and in some aspect metallic contact areas on opposite sites and facing each other. Any further processing can therefore follow conventional techniques, which reduces the number of necessary amendments in the manufacturing process. The resulting optoelectronic device shows an improved performance and improve quantum efficiency but can be processed further using well established processes.

The proposed idea is independent from the structure of the active region, that is the active region can comprise a quantum well structure, one or more quantum dots or a multi quantum well structure. A hetero structure is also possible. To prevent diffusion of doping material into the active region, the active region may be covered by one of more, in particular undoped cladding layers. One of those cladding layers can be adjacent to the current blocking layer. In some aspects, material of the contact layer is in electric contact with the regrown conductive barrier layer covering the structured boundaries.

In some aspects, the contact layer and other layers are to some extent absorbing. To reduce absorption of light opposite the main emission surface, it is suitable in some aspects to further create a reflective-particularly dielectric layer-deposited on the first current blocking layer. Such layer may be in the form of a DBR structure to reflect incident light generated in the active region. In this regard, material of the contact layer may also be reflective, or at least some reflective metal may be arranged on the contact layer.

In some aspects, the regrown conductive barrier layer comprises a multilayer of at least two semiconductor layers. It can be suitable to utilize doped semiconductor material that is also used for the other one of the p-doped and n-doped layer of the layer stack. By this, one can re-use the material for the other one of the n-doped and p-doped layer in a regrowth process to form the regrown conductive barrier layer on the edges of the active region and the doped layer above the blocking layer. The thickness of the regrown conductive barrier layer can be as thin as several tens of nm, like for instance between 20 nm to 100 nm and or between 20 nm and 50 nm. Consequently, the overall size of the device is kept small, while the regrown layer provides a sufficiently high barrier to significantly reduce the diffusion.

Some further aspects concern the material of the regrown conductive barrier layer and more particular the material of its multilayer. As previously mentioned, some of the material corresponds to the respective other one of the n-and p-doped layer. The regrown conductive barrier layer may also comprise an InAP layer,-particular a doped InAIP layer-, adjacent to the active region. Alternatively, a ZnSSe layer can be grown adjacent to the active region, as ZnSSe can be lattice matched.

In some instances, the conductive barrier layer comprises a multilayer comprising at least a doped InGaAlP layer and a doped InAlP layer, the latter layer grown on the boundary material of the active region. The first current blocking layer comprises a semiconductor multilayer in some instances. The plurality of layers is of different doping types. In particular it is a npnp multilayer when viewed from the direction of the active region.

The contact layer comprises a metal and/or a conductive oxide in some instances.

Some aspects concern the lateral thickness of regrown conductive barrier layer. In some aspects, the portion of the regrown conductive barrier layer extend substantially parallel to the one of the n-doped and p-doped layer. It may comprise a lateral thickness of about 100 nm to 500 nm and particularly below 400 nm.

Some aspects concern the regrown conductive barrier layer and further aspects of it. The regrown conductive barrier layer may be in electrical contact with a contact layer and also covers the structured boundaries of the active region. Particularly, the regrown conductive barrier layer covers the edges of the active region. While preventing with its large bandwidth material charge carriers from reaching the NRR centres, it can also be used to inject charge carriers through the regrown conductive barrier layer into the active region along the edges and boundaries of said active region.

Injection from the edges into the active region and not from the top (or bottom) may reduce the NRR. Consequently, the optoelectronic device further comprises a second current blocking layer arranged adjacent to the active region and surrounded by material of the regrown conductive barrier layer, wherein the contact layer that is in electric contact with the regrown conductive barrier layer is optionally at least partially arranged on the current blocking layer. The second current blocking layer prevents charge carrier injection into the active region from the top or bottom. Carrier injection is from the side through the conductive barrier material.

The second blocking layer can also comprise a semiconductor multilayer, comprising a plurality of layers of different doping types. The second blocking layer can have the same structure as the first blocking layer. This will simplify processing of the device, as such multilayer can be epitaxially grown. The second current blocking layer can comprise in particularly a pnpn multilayer when viewed from the direction of the active region.

In some instances, the first and/or the second current blocking layer may comprise a thickness in the range of 50 nm to 300 nm and particularly less than 250 nm. The thickness of the different layers may be in some aspects substantially equal. A thickness of each layer of the plurality of layers may be as thin as several tens of nm. The various layers can be based on the same material system, but with different doping to form the above mentioned pnpn and npnp multilayer, respectively. In some further instances, the material for the current blocking layer multilayer is the same as one of the n-doped and p-doped layer, particularly the layer that is in conductive contact with the regrown conductive material. More particularly, the one or more doped layers of the current blocking layer are based on the AlInP semiconductor material.

The material of the first and/or second current blocking layers comprise different doping concentration in the range of 1E15/cm³-1E19/cm³. This is optimized in each layer to maximize current blocking.

In some further instances, the optoelectronic device comprises a dielectric layer, particularly one of Al2O3 and SiO2 covering portions of the regrown conductive barrier layer facing away the active region. Furthermore, the optoelectronic device may comprise structured inclined sidewalls that extend from the one of the contact layers in electric contact with the regrown conductive barrier layer along a first portion having a first angle and along a second portion having a second angle towards the other contact layer.

Another aspect is related to processing an optoelectronic device. After providing a growth substrate, for example a GaAs substrate, a semiconductor layer stack is epitaxially grown on the growth substrate. This includes providing one of an n-doped layer and a p-doped layer on the growth substrate. Then, a first current blocking layer is epitaxially grown on the one of an n-doped layer and a p-doped layer. The first current blocking layer is structured, for example by applying a photomask on said layer and subsequently etching the exposed surface of the first current blocking layer. As a result of the structuring, a central opening is formed. The opening is then filled with a conductive material. the active region is grown on the structured first blocking layer.

A mask layer may then be provided on the active region and subsequently structured to cover portions over the active region. Using the structured mask, a first etch is performed to form mesa structures exposing boundaries of the active region. The etching process is stopped at the first current blocking layer, such that it is left intact. The resulting mesa structure with the exposed side walls of the active region is subsequently overgrown by a conductive barrier layer. The regrown conductive barrier layer comprises a material adjacent to the active region with a larger bandgap than the active region. Finally, a contact layer is deposited electrically coupled to the regrown conductive barrier layer covering the structured boundaries of the active region. The contact layer is at least partially arranged on the first current blocking layer.

The proposed method provides a current blocking layer preventing charge carriers from flowing from the conductive barrier layer via an artificial pn junction into the one of the n-and p-doped layer. This is achieved by the current blocking layer, that—while in itself comprising conductive material forms an electric barrier creating an electric potential in reverse direction. The regrown conductive barrier layer reduces the amount of NRR at the boundaries of the active region. With the proposed method the overall performance of an optoelectronic device, particular at very small sizes in the range of a few μm is improved.

In some instances, growing the active region comprises forming a quantum well structure or a multi-quantum well structure. Alternatively, a heterostructure can be formed, or a plurality of quantum dots grown. In some instances, the growth of an active region comprises growing one of more, in particular undoped cladding layers, one of said cladding layers adjacent to the current blocking layer.

In some aspects, the step of filling the opening with a conductive material comprises: a growth of a doped layer of the same doping type as the one of an n-doped layer and a p-doped layer into the opening. The doping concentration may be similar. The active region is then grown on the doped layer and the structured first current blocking layer.

The contact layer can be deposited at least partially on the regrown conductive barrier layer covering the boundaries of the active region. The material of the contact layer may also extend onto the current blocking layer. As a further alternative, a reflective dielectric layer can be deposited on the first current blocking layer, said reflective dielectric layer comprising at least one of a DBR structure and/or a reflective material. The DBR structure may be configured to reflect light emitted from the active region thereby improving the overall performance and light efficiency.

Some aspects concern the conductive barrier layer. It is possible to grow an InAlP layer,—particular a doped InAlP layer—, adjacent to the active region. As an alternative a lattice matched ZnSSe layer is also suitable to be grown adjacent to the active region. Further, alternatively, a multilayer can be grown comprising at least a doped InGaAlP layer and a doped InAlP layer.

In some instances, a doped GaP layer is grown, said GaP layer optionally adjacent to the contact layer. As GaP is lattice mismatched, other layers for lattice matching, as the one stated above are suitable.

In some aspects, regrowing a conductive barrier layer is followed by the step of conducting a second etch to remove portions of the regrown conductive barrier layer surrounding the layer stack such that a portion of the regrown conductive barrier layer extending substantially parallel to the first current blocking layer remains.. This is done to electrically isolate and later on to optically isolate each pixel.

Some further aspects concern an injection of carriers not from the top into the active region, but via the conductive barrier layer from the side edges. Hence, the proposed method further comprises growing a second current blocking layer on the active region. Said second current layer is subsequently structured by the first mesa etch process and subsequently overgrown.

The first blocking layer and second blocking layer may comprise similar structures and material including a plurality of differently doped layers. For example the first blocking layer may comprise a npnp multilayer when viewed from the direction of the active region. The second current blocking layer may comprise in particular a pnpn multilayer when viewed from the direction of the active region. The multilayer is epitaxially grown using different doping types and subsequently structured. The doping is optimized to increase blocking.

In some instances, the first and/or the second current blocking layer comprises a thickness in the range of 100 nm to 300 nm, particularly less than 250 nm,. Alternatively or additionally, a thickness of each layer of the plurality of layers as thin as several tens of nm.

In some other instances, the same material is used as used in the one of the n-doped and p-doped layer, particularly the layer that is in conductive contact with the regrown conductive material. For example, the first and/or the second current blocking layer may comprise a plurality of differently doped AlInP semiconductor material layer. In some other instances, the first and/or second current blocking layer may comprise a dielectric material.

### BRIEF DESCRIPTION OF THE DRAWINGS

Further aspects and embodiments in accordance with the proposed principle will become apparent in relation to the various embodiments and examples described in detail in connection with the accompanying drawings in which

FIG. 1 shows a first embodiment of an optoelectronic device in accordance with some aspects of the proposed principle;

FIG. 2 illustrates a second embodiment of an optoelectronic device in accordance with some aspects of the proposed principle;

FIG. 3 shows a third embodiment of an optoelectronic device in accordance with some aspects of the proposed principle;

FIG. 4 illustrates a fourth embodiment of an optoelectronic device in accordance with some aspects of the proposed principle;

FIGS. 5A to 5L illustrate an embodiment for a method of processing an optoelectronic device in accordance with some aspects of the proposed principle;

FIGS. 6A to 6C show some further aspects for a method of processing an optoelectronic device in accordance with some aspects of the proposed principle; and

FIG. 7 illustrates an embodiment for a current blocking layer in accordance with some aspects of the proposed principle.

### DETAILED DESCRIPTION OF ILLUSTRATIVE EMBODIMENTS

The following embodiments and examples disclose various aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

It is also noted herein that the given base material systems like InAlP or InGaAlP can have variations in their content. It is an exemplary system for the purpose of illustration and shall not limit the proposed principle to such system. For example, material InGaAlP may comprise different percentages of In, Ga and Al contents and can be also expressed in In_{y}(GaₓAl₁₋ₓ)P, whereas x and y are corresponding parameters and can vary depending on the desired wavelength for the emitted light and/or suitable barrier differences in the bandgap. For example, in a multi quantum well heterostructure, one changes the Al content between o to 1 to provide a quantum well layer or a barrier layer. A parameter x of o, x=o corresponds to an InAlP layer. Changing the In content usually varies the lattice constant and can be used to induce strain in the crystal that also varies the bandgap. Hence different In contents are used to adjust the emitted light to the desired wavelength.

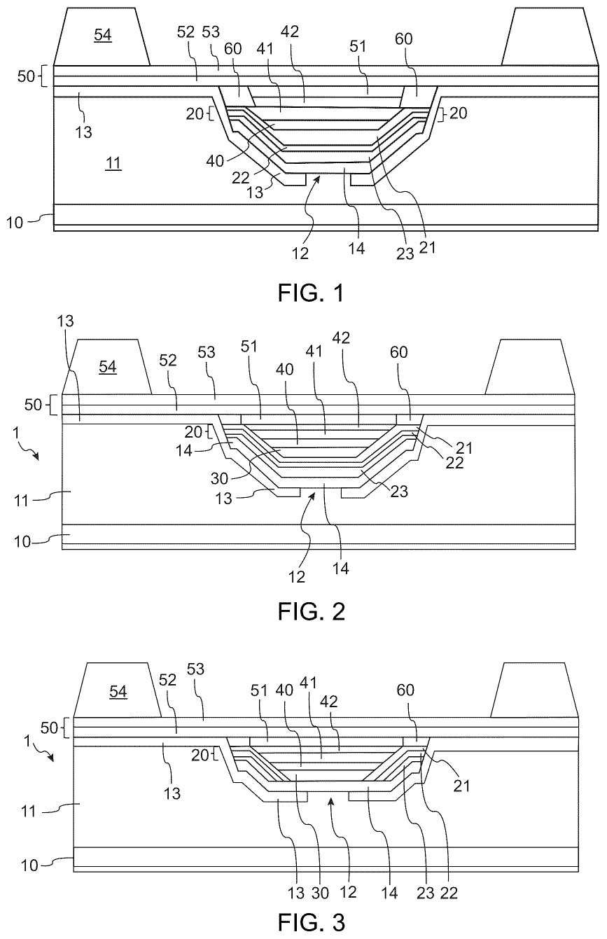

FIG. 1 illustrates a first embodiment in accordance with some aspects of the proposed principle. It should be noted that the embodiment of FIG. 1 as well as the further embodiments illustrate an optoelectronic device with a current blocking layer on its respective p-doped side. However, a person skilled in the art will recognize that the respective current blocking layers proposed by the present application can also be implemented on the n-doped side. Variations of the structure of the n-and p-doped layers in terms of material composition or doping concentration as well as the structure of the optoelectronic device can be implemented without deviating from the proposed idea.

The optoelectronic device comprises a carrier wafer substrate 10, which may be used as a wafer for further processing the optoelectronic device but can also-in other implementations-include circuitry for addressing the optoelectronic device during operation and supplying it with the respective current and voltage. The optoelectronic device is embedded in a mirror and bonding metal 11, which surrounds a semiconductor stack layer including an active region 41. The mirror and bonding layer 11 serve the purpose for providing an electrical contact to the layer stack, but also provides a reflective surface to improve the overall emission efficiency. During processing of the device, the mirror and bonding metal layer 11 is deposited to cover layer stack, such that re-bonding and a stable structure is secured. Layer 11 remains afterwards.

The semiconductor layer stack comprises inclined sidewalls, which, when viewed from the direction of contact hole 12 resemble a pyramid structure. The inclined sidewalls and the pyramid structure is formed by two Mesa etching processes as it will be explained in the subsequent figures.

The optoelectronic device comprises a bottom opening 12 connecting the reflective and conductive metal of the mirror and bonding metal stack 11 to conductive contact layer 14 of the layer stack. The present embodiment of the contact layer 14 is made of a conductive transparent oxide. The contact layer 14 is covered by a dielectric layer 13 which extends from the bottom contact hole 11 on the sidewall of the layer stack all the way up, separating the mirror and bonding metal 11 from the n-doped layer 50 structure.

The contact layer 14 is in electrical connection with a conductive barrier layer 20, comprising a GaP layer 23, an p-doped indium gallium aluminum phosphide, InGaAlP layer 22 and a p-doped indium aluminum phosphide InAlP barrier layer 21, respectively. The conductive barrier layer 20 therefore comprises a multilayer of several p-doped und undoped layers for transporting the respective charge carriers induced by contact layer 14 towards the active region 41. As illustrated, the conductive barrier layer 20 extends on the sidewall of the layer stack as well as on the bottom part of the layer stack (the bottom part being the portion of the layer stack with the smallest diameter).

In accordance with embodiments of the present invention, an undoped cladding layer made of indium gallium aluminum phosphide InGaAlP 40 is provided followed by an undoped active region 41. A second cladding layer 42 made of the same material is grown on the active region 41 opposite the first cladding layer 40. Both cladding layers are optional but shall prevent in this embodiment an undesired dopant diffusion into the active region 41. Their thickness lies in the range of a few 10 nm.

Active region 41 comprises an undoped quantum well or a undoped multi-quantum well structure made of indium gallium aluminum phosphide InGaAlP with different aluminum contents to provide a plurality of alternating barrier layers and quantum well layers, respectively. Cladding layer 42 also extent partially onto a portion of the barrier layer 21 extending substantially parallel to the n-dope layer structure 50.

As shown, the conductive barrier layer 20 and particularly layer 21 encapsulates the active region along its inclined sidewalls but also extends at least partially parallel to the n-doped layers 52 and 53, respectively in the outer region of the device. This extension of the conductive barrier layer 20 is due to the etching process of the mesa etch and the subsequent re-growth process. In particular, the second mesa etch, etching the material of the conductive barrier layer, requires a higher tolerance due to possible mismatch, thus generating the illustrated configuration with a small portion extending in parallel to the n-doped layers. The conductive connection between this portion of layer 21 and the n-doped layers can create a pn-or a pin junction resulting in a small yet possible leakage current that degrades the overall performance of the device. To prevent the above-mentioned leakage current by the artificial pin-or pn-junction, a first blocking layer 60 is arranged between the p-doped barrier layer 21 and the n-doped layer 52. The first blocking layer 60 comprises a npnp multilayer when viewed from the direction of the active region. The npnp multilayer generate an electrical blocking barrier and acts as a thyristor (without gate connection) preventing a current flow.

An opening in the first blocking layer 60 is provided and filled with conductive indium aluminum phosphide, InAlP barrier material 51. Thus, charge carriers from the n-doped current spreading layers 52 and 53, respectively are injected into the active region 41 through layer 51, while holes, are injected by the conductive barrier layer 20 into the top as well as on along the sidewalls of active region 41. At the same time, the npnp structure of the first blocking layer 60 prevents any artificial current from the conductive barrier layer to the n-doped layer bypassing the active region.

As previously mentioned, when viewed from the bottom a conductive indium aluminum phosphide InAlP barrier layer 51 is arranged on top of the second cladding layer 42 and limited in its lateral dimension by dielectric layer 13. Two current spreading layers corresponding to layer structure 50, having an n-doping type, namely layers 52 and 53 are arranged on the undoped indium aluminum phosphide, InAlP barrier layer 51 and dielectric layer 13. The n-doped layer structure 50 comprises an n-doped indium aluminum phosphide spreading layer 52 and n-doped indium gallium aluminum phosphide, contact layer 53. Finally, a grid structure 54 is provided for carrier injection.

Conductive barrier layer 20 comprises-as illustrated-a multilayer of three different layers 21, 22 and 23, which in itself are made of different materials. This results in an increase of the respective bandgap compared to the bandgap of the active region 41. While active region 41 comprises for example bandgap of about 2.0 eV, the indium aluminum phosphide, InAlP barrier material of layer 21 already comprises a higher bandgap of around 2.2 eV. The third layer 23 made of a gallium phosphide, GaP comprises an even higher bandgap of about 2.3 eV.

Instead of using the materials as illustrated herein for the conductive barrier layer, other crystal matched materials are suitable. Examples for such material are ZnSSe or AlAs, which comprise an even higher bandgap with approximately the same the crystal lattice. The thickness of the barrier layer depends on the size of the pixel and pixel and can be as thin as a few tens of nm. The thickness of first current blocking layer 60 is in the range of about 100 nm or more depending on the respective individual layers of the multilayer. When using a npnp structure, each layer has a thickness larger than a few tens of nm and strong doping concentration in the range of 1E15/cm³ to 1E19/cm³, optimized to maximize blocking.

A current blocking layer can also be provided on between the conductive barrier and the active region, thereby forcing carrier injection also the sidewalls of the active region.

FIG. 2 illustrates a corresponding embodiment. A second current blocking layer 30 is provided between the conductive barrier layer 20 and the active region 41. Between current blocking layer 30 and the active region 41, an undoped cladding layer made of indium gallium aluminum phosphide InGaAlP 40 is provided. The second blocking layer 30 comprises a pnpn-doped multilayer when viewed from the direction of the active layer 41. The structure prevents any charge carrier from layers 23, 22 and 21 from being injected into the active region 41 through its main surface. Rather, any charge carriers will flow along the inclined sidewalls of the conductive barrier layer 20 and into the active region 41 along its respective side edges. In other words, the conductive barrier layer provides an efficient lateral injection and spreading of charge carriers into the active region from the side, whereas injection from the top or bottom is prevented by current blocking layer 30. The current blocking layer 30 thereby prevents or significantly reduces the vertical electron overflow, which may otherwise cause the non-radiative recombination.

FIG. 3 illustrates a further alternative of the optoelectronic device with two blocking layers 30 and 60, respectively. In the embodiment, the overall height of the optoelectronic device is further reduced, by applying the contact layer 14 directly on top of the second blocking layer 30 It is noted in this regard that second current blocking layer 30 is optional here and the device can be processed without such structure of layer 30 further reducing the overall height. Consequently, this allows implementing very thin optoelectronic devices. During re-growth, the conductive barrier layer 20 is grown on top of blocking layer 30 as well as on the mesa etched sidewalls of the layer stack. However, since current blocking layer 30 will prevent any carrier injection into the active region through the respective main surface (main top or bottom of active region 41), the material of conductive barrier layer 20 can be omitted from the top of current blocking layer 30 and replaced by the material of the contact layer 14.

This embodiment is illustrated in FIG. 3, in which a transparent conductive oxide of contact layer 14 is deposited directly on the top of second current blocking layer 30. This can be achieved by using a dielectric etch and selective area regrowth mask (not shown), for the etching of the mesa and the regrowth of the conductive barrier layers, so that no regrowth occurs on top of the blocking layer and regrowth happens only on the sides of the structure. Then this mask can be removed and the contact layer 14 can be deposited. The structure can also be achieved by an additional etching or polishing process, without using a selective regrowth mask. After the regrowth of the conductive barrier layer 20, the material of conductive barrier layer 20 is covered by a structured mask layer (if removal by etching, not needed for removal by polishing) exposing the portions of conductive barrier layer 20 on the top of current blocking layer 30. Those exposed portions are removed in a subsequent etching process. Similarly polishing can remove the layers 20 on top, and after removal of the mask material, contact layer 14 is deposited on the sidewalls of the remaining conductive barrier layer 20 and the top portion of current blocking layer 30.

The dielectric material 13 in the present embodiments is usually made of silicon dioxide, SiO2 or any other transparent nonconductive material. In operation of the device, active region 41 will emit photons in each direction. The metal material of layer 11 is partially used to reflect the light being emitted towards the bottom direction of the layer stack (the bottom being the portion of the layer stack with its smallest diameter). However, there is a likelihood that photons emitted by the active region 41 are subsequently absorbed in contact layer 14 or the conductive material barrier layer 20. To reduce such undesired photon absorption and improve the overall emission efficiency, a reflective layer 70 can be provided on top of current blocking layer 30 as well as the adjacent sides of conductive barrier layer 20. This reflective additional layer 70 will increase the reflection properties and reduce the likelihood of absorption of photons emitted along the bottom direction.

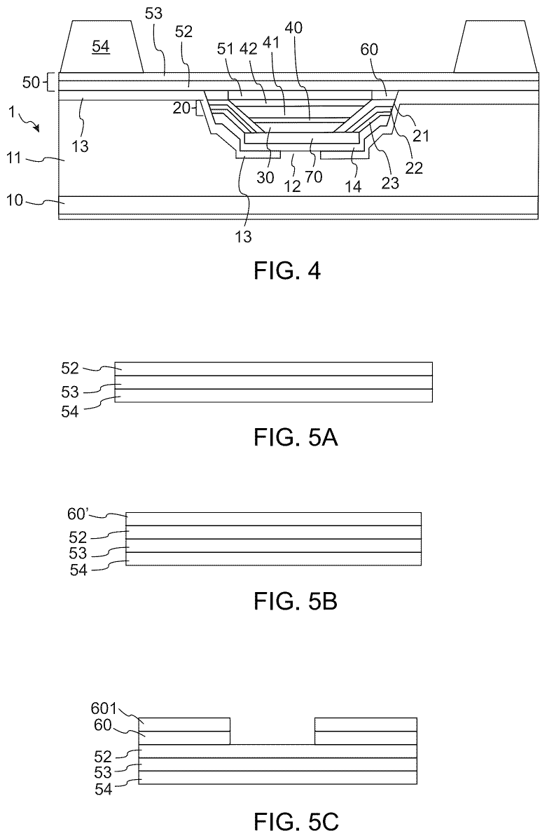

FIG. 4 illustrates the respective embodiment. The optoelectronic device 1 comprises the layer stack as previously explained in greater detail with second current blocking layer 30 grown on active region 41 and encapsulated by conductive barrier layer material 20. A contact layer 14 is in contact with metal contact 12 through the central opening of dielectric material 13 covering the layer stack and extends along the sidewalls on the conductive barrier layer 20. In accordance with this embodiment, a reflective layer portion 70 is provided between contact layer 14 and current blocking layer 30, extending on the edge surface of blocking layer 30 as well as on the surrounding conductive barrier layer 20. In some aspects, reflective layer 70 is a remaining portion of the hard mask used for the mesa etching and regrowth processes of layer 20. In some instances, reflective layer 70 is a DBR structure (also usable as hard mask for the mesa etching and regrowth processes) to reflect any light emitted towards the bottom area of the device. This will reduce the absorption in the contact layer 14. It is noted in this regard that in some embodiments, the second current blocking layer 30 can be omitted and the reflective layer, i.e. in form of a DBR structure directly arranged adjacent to the active region and optional cladding layer 41, respectively.

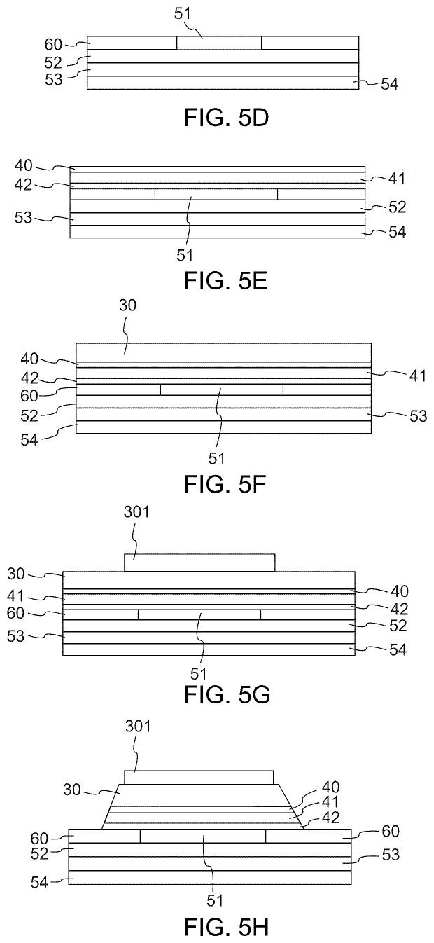

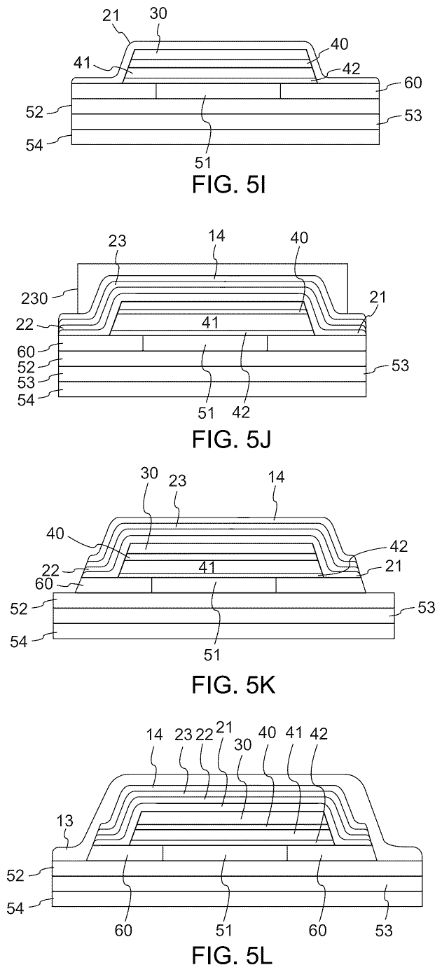

FIG. 5A) to 5L) illustrate several steps for processing an optoelectronic device in accordance with some aspects of the proposed principle. FIG. 5A) shows the first steps of growing a plurality of n-doped layers 53 and 52 on a corresponding growth substrate 54. The growth substrate may for example comprise GaAs. Such substrate supports growth of the subsequent layers thereby reducing crystal mismatches and defects during growth of the various layers.

Layers 53 and 52 are n-doped with different or constant doping profiles to provide a good contact to a metallic layer for conductively contacting the subsequently grown semiconductor stack as well as provide a current spreading. For example, layer 53 comprises an indium gallium aluminum phosphide, InGaAlP contact layer, which is doped in the range of larger than 1E17 atoms/cm³. The subsequently grown layer 52 comprises an indium aluminum phosphide spreading layer also n-doped with concentration >1E17 atoms/cm3. Other layers can be applied to the growth substrate prior to growing the two n-doped layers 53 and 52, in between or even on top of them. Additional growth adjustment layers between substrate 54 and n-doped layer 53 can be used to adjust crystal structures and reduce the lattice mismatch.

Continuing with FIG. 5B), first current blocking structure 60 based on the indium aluminum phosphide InAlP material system is grown on the top surface of n-doped current spreading layer 52. The current blocking layer 60 comprise a plurality of layers having different doping types. In view of the growth direction, the different doping types follow a pnpn structure with a doping level between 1E17 1/cm³ and 1e19 1/cm³ for example. The first current blocking layer 60 will prevent a leakage current between the n-doped layer and the different p-doped layers of the subsequently regrown layer stack and therefore reduce the current leakage through the optoelectronic device in operation.

In FIG. 5C), first current blocking layer 60 is subsequently structured by applying a structured resist or dielectric mask layer 601 to its surface and etching a portion of current blocking layer 60 to expose the n-doped current spreading layer 52 beneath. The exposed area will subsequently form a seed for the layer stack of the optoelectronic device. The opening is overgrown with an indium aluminum phosphide, InAlP layer 51, as illustrated in FIG. 5D. The mask 601 can be removed optionally before or after (only for the dielectric mask case) the regrowth of layer 51. The FIG. 5D shown is for the case where the mask 601 is a dielectric and is removed after the regrowth of layer 51.

The conductive layer 51 ensures charge carrier transport from the n-doped current spreading layer 52 into the active region subsequently grown on the surface of current blocking layer 60 and the layer 51 as shown in FIG. 4.

In particular shown in FIG. 5E), an undoped thin cladding layer 42 (a few 10 nm thick) is grown on the top surface, followed by a multi-quantum well structure 41 made of the plurality of barrier layers and quantum well layers, respectively. The base material used for the multi quantum well structure is a ternary or a quaternary system, for example made of indium gallium aluminum phosphide InGaAlP with different aluminum content for the barrier layers and the quantum well layers, respectively. On top of the active region 41, a second cladding layer 40 is grown. Both cladding layers 42 and 40 comprise an undoped indium gallium aluminum phosphide InAlGaP layer. Their thickness lies in the range of a few 10 nm. The composition of the Ga, Al and In amounts of the various cladding layers 40 and 42 on the one hand and the active region on the other may vary to obtain a certain bandgap transition within the structure to capture charge carriers within. The undoped cladding layers are optionally added, e.g. to prevent diffusion of dopant during processing and later operation into the active region.

Following now with next process step illustrated in FIG. 5F), namely the growth of another, yet optional current blocking layer 30 based on the indium aluminum gallium phosphide, InGaAlP material system. Consequently, in some embodiments this step can be omitted, e.g. to provide an optoelectronic device according to FIG. 1. The multilayer again comprises a plurality of differently doped layers. In this case a pnpn multilayer is grown when viewed from the active region 41. The doping level of the multilayer that is the p-and n-doping is in the range of 1E15 atoms/cm³ to 1E19/cm³ in the respective layers. In the given range, the doping concentration and thicknesses are set to ranges such that tunnelling of charge carriers does not or substantially not take place.

In the next processing step shown in FIG. 5G), a hard mask material is deposited on top of current blocking layer 30 and subsequently structured to provide a pillar of mask layer material 301 arranged substantially centrally over the area of undoped layer 51.

A first Mesa etching step is performed in a subsequent step using mask layer 301 down to the first current blocking layer 60, exposing the sidewalls of the active region 40, the second blocking layer 30 as well as the two cladding layers 41 and 42. In a top view, the Mesa etching is performed in a pyramid like structure exposing the sidewalls. The resulting structure is shown in FIG. 5H.

After removal of the hard mask 301 in the present embodiment, a regrowth process takes place in FIG. 51) forming a layer of p-doped material 21 on the top surface of current blocking layer 30 as well as on the sidewalls of the exposed active region 40 extending partially onto the top surface of first current blocking layer 60. Said layer 21 forms the first layer of the conductive barrier layer 20 as illustrated.

More particularly, material of layer 21 comprises a p-doped indium aluminum phosphide, InAlP barrier material. On top of layer 21, a second layer 22 of p-doped indium gallium aluminum phosphide, InGaAlP is grown, which in turn is covered by a gallium phosphide, GaP layer 23, which is also the semiconductor contact layer. The three layers 21, 22 and 23 form the conductive barrier and contact layer 20 connecting the active region 40 from its side edges. Finally, as shown in FIG. 5J), a contact layer 14 made of a transparent conductive oxide is deposited on top of the gallium phosphide, GaP layer 23 covering the top portion, the sidewalls and partially extending over the second current blocking layer 60.

Then also shown in FIG. 5J), the structure is partially covered by structured mask layer 230, which extends all across of the layer stack, its sidewall and over a portion of the conductive barrier material as well as the contact layer 14 parallel to current blocking layer 60 is covered by the material of mask layer 230. The lateral dimension of mask layer 230 is set such that any misalignment of mask layer 230 still covers the layer stack, but also leaves some room such that charge carriers diffusing into the conductive barrier material are substantially kept away from the outer side edges (subsequently formed by etching) of the conductive barrier material.

In a subsequent step shown in FIG. 5K, a second mesa etch is performed forming the second sidewalls exposing the conductive barrier layers 21, 22 and 23, as well as of the contact layer 14. The second mesa etching is performed until the top surface of n-doped layer 52 is exposed. The inclination of both mesa etches can be the same as shown in this exemplary methods, but may also be different, e.g. as illustrated in the embodiments of FIG. 1 to 4. Dielectric material 13 for example made of SiO2 is deposited on top of the n-doped layer 52 as well as on the respective exposed sidewall portions and the top of the contact layer 14.

The resulting structure is illustrated in FIG. 5L). After providing an opening in the dielectric material of layer 13 to expose a portion of the transparent conductive oxide 14 a reflective metal stack is deposited to provide a contact to the conductive layer 14. The metal stack also stabilizes the structure and facilitates rebonding and removing the growth substrate 54. After removal of growth substrate 54 (not shown here), additional processing can be performed such as applying a metallic contact grid.

The resulting structure resembles and corresponds to the embodiment of FIG. 2. By omitting the growth and structuring of the current blocking layer 30 one can achieve a structure of the embodiment of FIG. 1.

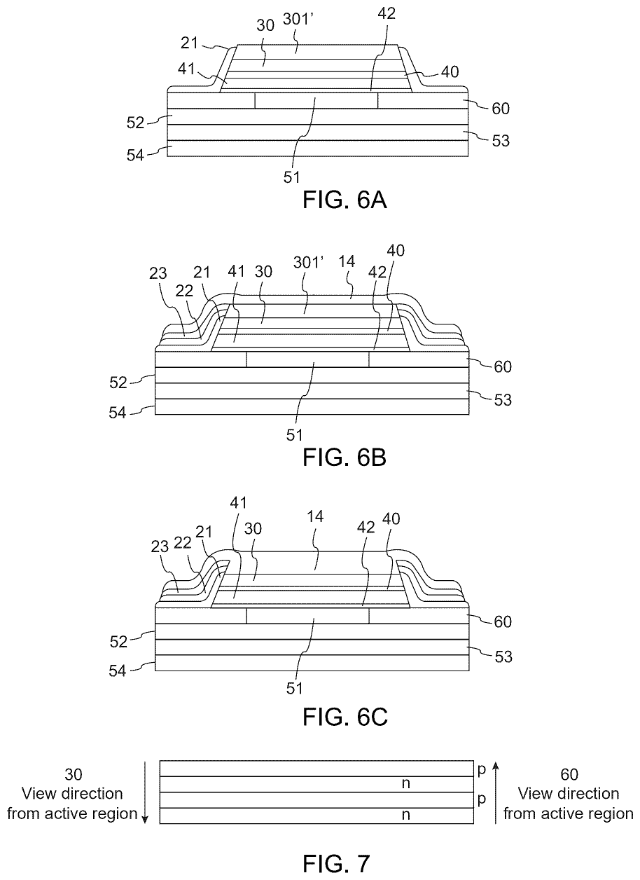

FIG. 6A) to 6B) illustrate two further steps for processing an optoelectronic device in accordance with the embodiment of FIG. 4. In this particular case, a mask layer 301′ is provided on the top surface of the current blocking layer 30. However, in the present case, mask layer 301′ comprises a DBR structure, that is a multilayer of materials with different refractive indices to reflect light emitted in the active region towards the heterostructure 301′. After structuring the mask layer 301′ and the active layer, similar steps are performed to grow the conductive barrier material layers 21, 22 and 23. In the present example, the growth of the respective material is selective, that is the material mainly grow on the exposed sidewalls of the active region 41 and the cladding layers 40, 42 as well as on the top portion of current blocking layer 60. This can be achieved, for example, by careful adjustment of the growth parameters during the regrowth process.

In an alternative embodiment mask layer 301′ is omitted and the exposed surface of cladding layer 41 is directly overgrown by the layers of barrier layer 20 resulting in the embodiment of FIG. 1.

FIG. 6B) illustrates the result of that regrowth process, in which the material of conductive barrier layer 20 is mainly grown on the top surface of first current blocking layer 60 and on the exposed sidewalls of the semiconductor layer stack with the active region 41, the two cladding layers 40 and 42 as well as the current blocking layer 30, but not on top of mask layer 301′. Finally, a conductive transparent oxide or metal layer 14 is deposited on the conductive barrier 20 as well as on the top surface of the mask layer 301′. Mask layer 301′ therefore remains in the optoelectronic device forming the above-mentioned DBR structure or an otherwise reflective structure to improve the outcoupling of the light generated in the active region.

FIG. 6C) illustrates a slightly different process step, during and after the regrowth process. In this example, mask layer 301′ covering the top portion of current blocking layer 30 is removed after the regrowth process of the conductive barrier layer 20 and a transparent conductive oxide layer 14 is deposited on the sidewalls of the conductive barrier as well as on the top portion of current blocking layer 30. This embodiment corresponds to the embodiment of FIG. 3 and allows for a smaller vertical dimension of the optoelectronic device and reduced absorption from the omission of layers 20 above the blocking layer, when compared to the embodiment in FIG. 1. As in the previous embodiments, charge carriers provided by contact layer 14 are injected into the active region 40 through the conductive barrier 20 along the sidewalls.

By omitting the previous step illustrated in 5F) of growing the multilayer of blocking layer 30, contact layer 14 can be deposited directly on cladding layer 40. The thickness of cladding layer 40 in this regard is adjusted.

FIG. 7 illustrates an example of a current blocking layer multilayer, for example a npnp layer stack as grown for instance as current blocking layer 60 or a pnpn layer stack for current blocking layer 30. The npnp or pnpn layer stack comprises several differently doped layers, each of the layer having a thickness of a few tens of nm. The structure resembles a thyristor with a missing gate connection.

1-25. (canceled)

26. An optoelectronic device comprising:
a mesa structured semiconductor layer stack having at least one of an n-doped layer or a p-doped layer and a structured active region arranged on a respective one of the n-doped layer or the p-doped layer; the structured active region configured to emit light;
a regrown conductive barrier layer covering structured boundaries of the active region, the regrown conductive barrier layer comprising a material adjacent to the active region having a larger bandgap than the active region;
respective contact layers electrically coupled to at least the one of the n-doped layer or the p-doped layer, respectively, wherein one of the contact layers is in electric contact with the regrown conductive barrier layer covering the structured boundaries of the active region,
wherein a portion of the regrown conductive barrier layer extends substantially parallel to the one of the n-doped layer or the p-doped layer thereby surrounding the active layer;
a structured first current blocking layer arranged between the portion of the regrown conductive barrier layer and the one of the n-doped layer or the p-doped layer, the first current blocking layer comprising an opening,
wherein the one of the n-doped layer or the p-doped layer is in conductive contact with the active region through the opening in the current blocking layer.

27. The optoelectronic device according to claim 26, wherein the active region comprises one of:
a quantum well;
a multi-quantum well;
a hetero structure;
one or more quantum dots; or
one or more cladding layers, one of the cladding layers adjacent to the current blocking layer.

28. The optoelectronic device according to claim 26, wherein a material of the contact layer that is in electric contact with the regrown conductive barrier layer covering the structured boundaries is located on the regrown conductive barrier layer.

29. The optoelectronic device according to claim 26, further comprising a reflective dielectric layer located between the active region and the contact layer that is in electric contact with the regrown conductive barrier layer.

30. The optoelectronic device according to claim 26, wherein the regrown conductive barrier layer comprises a multilayer of at least two semiconductor layers comprising different material compositions and doping.

31. The optoelectronic device according to claim 26, wherein a thickness of the regrown conductive barrier layer is in a range of several tens of nm.

32. The optoelectronic device according to claim 26, wherein the regrown conductive barrier layer comprises at least one of:
a GaP layer optionally adjacent to the contact layer;
an InAlP layer adjacent to the active region;
a ZnSSe layer adjacent to the active region; or
a heterostructure comprising at least a doped InGaAlP layer and a doped InAlP layer.

33. The optoelectronic device according to claim 26, wherein the portion of the regrown conductive barrier layer extending substantially parallel to the one of the n-doped layer or the p-doped layer comprises a lateral thickness of about 50 nm to 500 nm.

34. The optoelectronic device according to claim 26, wherein the first current blocking layer comprises a semiconductor multilayer comprising a plurality of layers of different doping type.

35. The optoelectronic device according to claim 26, further comprising a second current blocking layer arranged adjacent to the active region and surrounded by the material of the regrown conductive barrier layer, wherein the contact layer is in electric contact with the regrown conductive barrier layer.

36. The optoelectronic device according to claim 35, wherein the second current blocking layer comprises a semiconductor stack, comprising a plurality of layers of different doping type.

37. The optoelectronic device according to claim 35, wherein the first current blocking layer and/or the second current blocking layer comprises at least one of:
a thickness of about 100 nm or more;
a thickness of each layer of a plurality of layers in a range several tens of nm;
the same material as one of the n-doped layer or the p-doped layer; or
one or more doped layers of AlInP semiconductor material.

38. The optoelectronic device according to claim 35, wherein a material of the first current blocking layer and/or the second current blocking layers comprises a doping concentration in a range of 1E15 atoms/cm³ to 1E19 atoms/cm³.

39. The optoelectronic device according to claim 26, further comprising a dielectric layer covering portions of the regrown conductive barrier layer facing away the active region.

40. The optoelectronic device according to claim 26, further comprising structured inclined sidewalls that extend from the one of the contact layers in electric contact with the regrown conductive barrier layer along a first portion having a first angle and along a second portion having a second angle towards the other contact layer.

41. A method for processing an optoelectronic device, the method comprising:
providing a growth substrate;
providing one of an n-doped layer or a p-doped layer on the growth substrate;
growing first current blocking layer on the one of the n-doped layer or the p-doped layer;
structuring the first current blocking layer such as to form a central opening;
filling the opening with a conductive layer;
growing an active region on the structured first blocking layer and the conductive layer;
performing a first etch to form mesa structures exposing boundaries of the active region;
the first etch stopping at the first current blocking layer;
re-growing a conductive barrier layer on the structured boundaries of the active region, the regrown conductive barrier layer comprising a material adjacent to the active region having a larger bandgap than the active region; and
providing a contact layer electrically coupled to regrown conductive barrier layer covering the structured boundaries of the active region.

42. The method according to claim 41, wherein growing the active region comprises one of:
growing a quantum well structure;
growing a multi-quantum well structure;
growing a hetero structure;
growing one or more quantum dots; and
growing one or more cladding layers, wherein one of the cladding layers is adjacent to the current blocking layer.

43. The method according to claim 41, wherein filling the opening with a conductive material comprises:
growing a doped layer of the same doping type as the one of the n-doped layer or the p-doped layer into the opening, and
growing the active region on the doped layer and the structured first current blocking layer.

44. The method according to claim 41, wherein providing the contact layer comprises depositing a contact layer material at least partially on the regrown conductive barrier layer covering the boundaries of the active region.

45. The method according to claim 41, further comprising forming a reflective dielectric layer prior to providing a contact layer, the reflective dielectric layer comprising at least one of a DBR structure and/or a reflective material.

46. The method according to claim 41, wherein re-growing the conductive barrier layer comprises at least one of:
growing an InAlP layer adjacent to the active region;
growing a ZnSSe layer adjacent to the active region;
growing a multilayer comprising at least a doped InGaAP layer and a doped InAlP layer; or
growing a GaP layer optionally adjacent to the contact layer.

47. The method according to claim 41, wherein re-growing the conductive barrier layer comprises performing a second etch to remove portions of the regrown conductive barrier layer surrounding a layer stack such that a portion of the regrown conductive barrier layer extends substantially parallel to the first current blocking layer.

48. The method according to claim 41, wherein providing a semiconductor stack comprises growing a second current blocking layer on the active region.

49. The method according to claim 48, wherein growing the first current blocking layer and/or second current blocking layer comprises growing a plurality of differently doped layers, the differently doped layers being a npnp layer multilayer and/or a pnpn multilayer when viewed from a direction of the active region.

50. The method according to claim 48, wherein the first current blocking layer and/or the second current blocking layer comprises at least one of:
a thickness of about 100 nm or more;
a thickness of each layer of the plurality of layers in a range several tens of nm;
the same material as one of the n-doped layer or the p-doped layer, the layer that is in conductive contact with a regrown conductive material; or
one or more doped layers of AlInP semiconductor material.
